(19) United States
(12) Patent Application Publication
(10) Pub. No.: US 2025/0194208 A1
(43) Pub. Date: Jun. 12, 2025

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Jiangsu (CN)

(72) Inventors: Xiao ZHANG, Jiangsu (CN); Lijie ZHANG, Jiangsu (CN); Jue OUYANG, Jiangsu (CN); Wen-Yuan HSIEH, Jiangsu (CN)

(73) Assignee: INNOSCIENCE (SUZHOU) SEMICONDUCTOR CO., LTD., Jiangsu (CN)

(21) Appl. No.: 18/856,065

(22) PCT Filed: Apr. 14, 2022
(86) PCT No.: PCT/CN2022/086849

§ 371 Date: Oct. 11, 2024

(51) Int. Cl. H10D 64/23; H01L 23/31; H10D 30/01; H10D 30/47; H10D 62/85; H10D 64/01

(52) U.S. Cl. CPC H10D 64/251; H01L 23/3171; H01L 23/3192; H10D 30/015; H10D 30/475; H10D 62/8503; H10D 64/01

(57) ABSTRACT

The nitride-based semiconductor device includes a first nitride-based semiconductor layer, a second nitride-based semi-conductor layer, a first passivation layer, and an electrode structure. The second nitride-based semiconductor layer is disposed on the first nitride-based semiconductor layer and has a bandgap greater than a bandgap of the first nitride-based semiconductor layer. The first passivation layer is disposed on the second nitride-based semiconductor layer. The electrode structure is disposed on the second nitride-based semiconductor layer and the first passivation layer and penetrates the first passivation layer to make contact with the second nitride-based semiconductor layer, in which the electrode structure has a sidewall extending upward from the first passivation layer and oblique with respect to the first passivation layer.

### FIELD OF THE INVENTION

The present invention generally relates to a nitride-based semiconductor device. More specifically, the present invention relates to a nitride-based semiconductor device having an ohmic contact electrode with an oblique sidewall.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE INVENTION:

In accordance with one aspect of the present disclosure, a nitride-based semiconductor device is provided. The nitride-based semiconductor device includes a first nitride-based semiconductor layer, a second nitride-based semiconductor layer, a first passivation layer, and an electrode structure. The second nitride-based semiconductor layer is disposed on the first nitride-based semiconductor layer and has a bandgap greater than a bandgap of the first nitride-based semiconductor layer. The first passivation layer is disposed on the second nitride-based semiconductor layer. The electrode structure is disposed on the second nitride-based semiconductor layer and the first passivation layer and penetrates the first passivation layer to make contact with the second nitride-based semiconductor layer, in which the electrode structure has a sidewall extending upward from the first passivation layer and oblique with respect to the first passivation layer.

In accordance with one aspect of the present disclosure, method for manufacturing a semiconductor device is provided. The method includes steps as follows. A second nitride-based semiconductor layer is formed on a first nitride-based semiconductor layer. A first passivation layer with an opening is formed over the second nitride-based semiconductor layer. A conductive layer is formed over the first passivation layer and within the opening so as to make contact with the second nitride-based semiconductor layer. A mask layer is formed to cover the conductive layer such that at least one portion of the conductive layer is exposed. The exposed portion of the conductive layer is removed by alternately etching the exposed portion of the conductive layer and forming a polymer layer on the exposed portion of the conductive layer, so as to make a sidewall of the remained portion of the conductive layer tilted.

In accordance with one aspect of the present disclosure, a nitride-based semiconductor device is provided. The nitride-based semiconductor device includes a first nitride-based semiconductor layer, a second nitride-based semiconductor layer, a first passivation layer, an electrode structure, and a second passivation layer. The second nitride-based semiconductor layer is disposed on the first nitride-based semiconductor layer and has a bandgap greater than a bandgap of the first nitride-based semiconductor layer. The first passivation layer is disposed on the second nitride-based semiconductor layer. The electrode structure is disposed on the second nitride-based semiconductor layer and the first passivation layer and penetrates the first passivation layer to make contact with the second nitride-based semiconductor layer. The second passivation layer is disposed on the second nitride-based semiconductor layer and the first passivation layer and covers a sidewall of the electrode structure, in which the second passivation layer forms an interface with the sidewall of the electrode structure, and the interface is oblique with respect to the first passivation layer.

By applying the above configuration, the configuration is made for better coverage by the second passivation layer. Since the sidewall is oblique, the deposition materials of the second passivation layer can land on the sidewalls of the electrode during the formation of the second passivation layer, thereby improving the yield rate of the semiconductor device.

### BRIEF DESCRIPTION OF THE DRAWINGS:

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a semiconductor device according to some embodiments of the present disclosure;

FIG. 1B is an enlargement view of the electrode of FIG. 1A according to some embodiments of the present disclosure;

FIG. 2A, FIG. 2B, FIG. 2C, FIG. 2D, FIG. 2E, and FIG. 2F show different stages of a method for manufacturing a nitride-based semiconductor device according to some embodiments of the present disclosure;

FIG. 3A is a vertical cross-sectional view of a semiconductor device according to some embodiments of the present disclosure;

FIG. 3B is a vertical cross-sectional view of a semiconductor device according to some embodiments of the present disclosure;

FIG. 4A is a vertical cross-sectional view of a semiconductor device according to some embodiments of the present disclosure;

FIG. 4B is a vertical cross-sectional view of a semiconductor device according to some embodiments of the present disclosure;

FIG. 5A is a vertical cross-sectional view of a semiconductor device according to some embodiments of the present disclosure; and

FIG. 5B is a vertical cross-sectional view of a semiconductor device according to some embodiments of the present disclosure.

### DETAILED DESCRIPTION:

Common reference numerals are used throughout the drawings and the detailed description to indicate the same or similar components.

Embodiments of the present disclosure will be readily understood from the following detailed description taken in conjunction with the accompanying drawings.

Spatial descriptions, such as “above,” “on,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement. Further, it is noted that the actual shapes of the various structures

depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

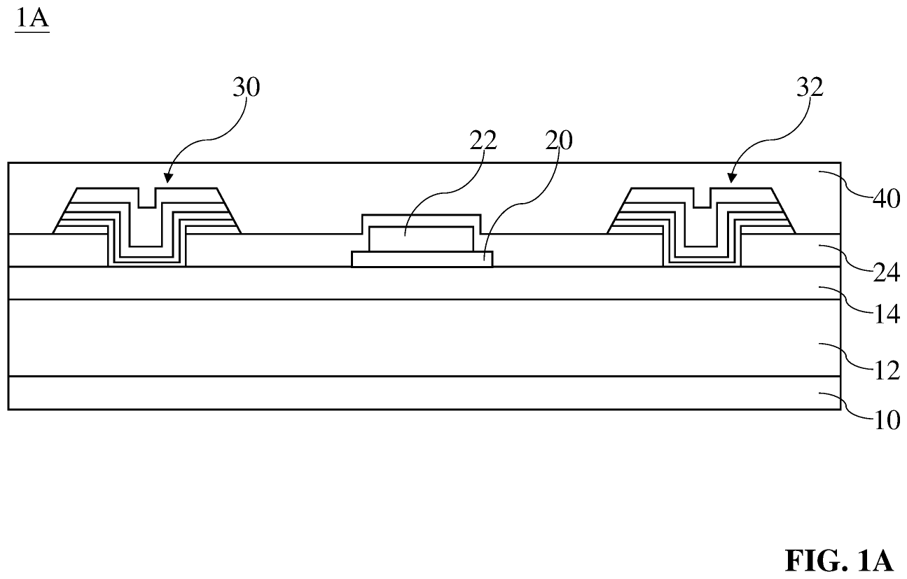

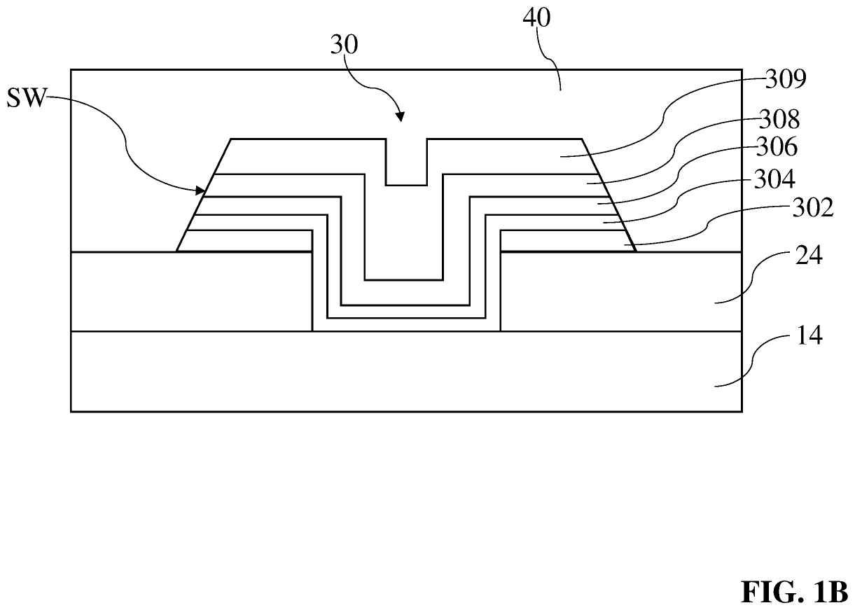

FIG. 1A is a vertical cross-sectional view of a semiconductor device 1A according to some embodiments of the present disclosure. The semiconductor device 1A includes a substrate 10, nitride-based semiconductor layers 12 and 14, a doped nitride-based semiconductor layer 20, a gate electrode 22, a passivation layer 24, electrodes 30 and 32, and a passivation layer 40.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

In some embodiments, the semiconductor device 1A may further include a buffer layer (not shown). The buffer layer is disposed over the substrate 10. The buffer layer can be configured to reduce lattice and thermal mismatches between the substrate 10 and the nitride-based semiconductor layer 14, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and a buffer layer. The nucleation layer can be configured to provide a transition to accommodate a mismatch/difference between the substrate 10 and a III-nitride layer of the buffer layer. The exemplary material of the nucleation layer can include, for example but is not limited to AlN or any of its alloys.

The nitride-based semiconductor layer 12 is disposed on/over/above the substrate 10. The nitride-based semiconductor layer 14 is disposed on/over/above the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, AlₓGa₍₁₋ₓ₎N where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 12 and 14 are selected such that the nitride-based semiconductor layer 14 has a bandgap (i.e., forbidden band width) greater than a bandgap of the nitride-based semiconductor layer 12, which causes electron affinities thereof different from each other and forms a heterojunction therebetween. For example, when the nitride-based semiconductor layer 12 is an undoped GaN layer having a bandgap of approximately 3.4 eV, the nitride-based semiconductor layer 14 can be selected as an AlGaN layer having bandgap of approximately 4.0 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The doped nitride-based semiconductor layer 20 and the gate electrode 22 are stacked on the nitride-based semiconductor layer 14. The doped nitride-based semiconductor layer 20 is located between the nitride-based semiconductor layer 14 and the gate electrode 22.

The semiconductor device 1A can be designed as being an enhancement mode device, which is in a normally-off state when the gate electrode 22 is at approximately zero bias. Specifically, the doped nitride-based semiconductor layer 20 creates a p-n junction with the nitride-based semiconductor layer 12 to deplete the 2DEG region, such that a zone of the 2DEG region corresponding to a position below the gate electrode 22 has different characteristics (e.g., different electron concentrations) than the rest of the 2DEG region and thus is blocked. Due to such mechanism, the semiconductor device 1A has a normally-off characteristic. In other words, when no voltage is applied to the gate electrode 22 or a voltage applied to the gate electrode 22 is less than a threshold voltage (i.e., a minimum voltage required to form an inversion layer below the gate electrode 22), the zone of the 2DEG region below the gate electrode 22 is kept blocked, and thus no current flows therethrough. Moreover, by providing the doped nitride-based semiconductor layer 20, gate leakage current is reduced and an increase in the threshold voltage during the off-state is achieved.

In some embodiments, the doped nitride-based semiconductor layer 20 can be omitted, such that the semiconductor device 1A is a depletion-mode device, which means the semiconductor device 1A in a normally-on state at zero gate-source voltage.

The exemplary materials of the doped nitride-based

semiconductor layer 20 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd. In some embodiments, the nitride-based semiconductor layer 12 includes undoped GaN and the nitride-based semiconductor layer 14 includes AlGaN, and the doped nitride-based semiconductor layer 20 is a p-type GaN layer which can bend the underlying band structure upwards and to deplete the corresponding zone of the 2DEG region, so as to place the semiconductor device 1A into an off-state condition.

In some embodiments, the gate electrode 22 may include metals or metal compounds. The exemplary materials of the metals or metal compounds can include, for example but are not limited to, W, Au, Pd, Ti, Ta, Co, Ni, Pt, Mo, TiN, TaN, metal alloys thereof, or other metallic compounds. In some embodiments, the exemplary materials of the gate electrode 22 may include, for example but are not limited to, nitrides, oxides, silicides, doped semiconductors, or combinations thereof. In some embodiments, the optional dielectric layer can be formed by a single layer or more layers of dielectric materials. The exemplary dielectric materials can include, for example but are not limited to, one or more oxide layers, a SiOₓ layer, a SiNₓ layer, a high-k dielectric material (e.g., HfO₂, Al₂O₃, TiO₂, HfZrO, Ta₂O₃, HfSiO₄, ZrO₂, ZrSiO₂, etc), or combinations thereof.

The passivation layer 24 is disposed over the nitride-based semiconductor layer 14. The passivation layer 24 covers the gate structure 14 for a protection purpose. The passivation layer 24 is conformal with the profile of the gate electrode 22 in combination with the doped nitride-based semiconductor layer 20. The exemplary materials of the passivation layer 24 can include, for example but are not limited to, SiNₓ, SiOₓ, SiON, SiC, SiBN, SiCBN, oxides, nitrides, or combinations thereof. In some embodiments, the passivation layer 24 is a multi-layered structure, such as a composite dielectric layer of Al₂O₃/SiN, Al₂O₃/SiO₂, AlN/SiN, AlN/SiO₂, or combinations thereof.

The electrodes 30 and 32 are disposed on/over/above the nitride-based semiconductor layer 14. The electrodes 30 and 32 are disposed on/over/above the passivation layer 24. The electrodes 30 and 32 penetrate the passivation layer 24 to make contact with the nitride-based semiconductor layer 14. The electrodes 30 and 32 and the gate electrode 22 can constitute a HEMT device with the 2DEG region. The electrodes 30 and 22 can serve as ohmic contact electrode in the HEMT device.

In some embodiments, the electrode 16 can serve as a source electrode. In some embodiments, the electrode 16 can serve as a drain electrode. In some embodiments, the electrode 18 can serve as a source electrode. In some embodiments, the electrode 18 can serve as a drain electrode. The role of the electrodes 20 and 22 depends on the device design.

In some embodiments, each of the electrodes 30 and 32 is an electrode structure that is formed from a plurality of layers. To illustrate, FIG. 1B is an enlargement view of the electrode 30 of FIG. 1A according to some embodiments of the present disclosure. The electrode 30 is multiple layered. The electrode 30 includes a nitride-based layer 302, conformal layers 304, 306, 308, and a filling layer 309.

The nitride-based layer 302 is disposed on the passivation layer 24. The nitride-based layer 302 is in contact with the passivation layer 24. In some embodiments, an entirety of the nitride-based layer 302 is in a position higher than the passivation layer 24. Accordingly, the nitride-based layer 302 is free form contact with the nitride-based semiconductor layer 14. In some embodiments, the nitride-based layer 302 can serve as an adhesion layer to connect other layers to the passivation layer 24. In some embodiments, the nitride-based layer 302 can serve as an etch stop layer during the formation of the electrode 30. In some embodiments, the nitride-based layer 302 includes titanium nitride (TiN).

The conformal layers 304, 306, 308 are disposed on the nitride-

based semiconductor layer 14 and the passivation layer 24. The conformal layers 304, 306, 308 are stacked over the nitride-based semiconductor layer 14 in sequence. The passivation layer 24 has an opening so that the conformal layers 304 can penetrate the passivation layer 24 to make contact with the nitride-based semiconductor layer 14. The nitride-based layer 302 is located between the passivation layer 24 and the conformal layers 304. The conformal layers 306 and 308 are separated from the nitride-based semiconductor layer 14 by the conformal layer 304.

In some embodiments, each of the conformal layers 304, 306, 308 can include, for example but are not limited to, a metal layer, a nitride-based layer, an aluminum-based, or combinations thereof. In some embodiments, the exemplary materials of each of the conformal layers 304, 306, 308 can include, for example but are not limited to, Al, AlSi, Ti, Ni, Pt, TiN, Au, or combinations thereof.

The filling layer 309 is disposed on the conformal layer 308. The filling layer 309 can extend to fill in a recess of the conformal layer 308. The filling layer 309 can serve as a top-most layer of the electrode 30. Since the filling layer 309 is conformal with the underlying profile, the filling layer 309 can have a top surface recessed inward. In some embodiments, the filling layer 309 can include, for example but are not limited to, a metal layer, a nitride-based layer, an aluminum-based, or combinations thereof. In some embodiments, the exemplary materials of the filling layer 309 can include, for example but are not limited to, Al, AlSi, Ti, Ni, Pt, TiN, Au, or combinations thereof.

The electrode 30 includes opposite sidewalls SW. The sidewalls SW of the electrode 30 are formed by the nitride-based layer 302, the conformal layers 304, 306, 308, and the filling layer 309 collectively. The sidewalls SW of the electrode 30 extends upward from the passivation layer 24. The sidewalls SW of the electrode 30 are oblique with respect to the passivation layer 24.

In some embodiments, each of the sidewalls SW of the electrode 30 can have an oblique angle with respect to the passivation layer 24 in a range from about 35 degrees to about 75 degrees. In some embodiments, each of the sidewalls SW of the electrode 30 has an oblique angle with respect to the passivation layer 24 at about 45 degrees. Such the configuration is made for better coverage by the passivation layer 40.

The passivation layer 40 is disposed on the passivation layer 24 and the electrode 30. In some embodiments, the passivation layer 40 covers an entirety of the sidewalls SW of the electrode 30.

During the formation of the passivation layer 40, at least one material of the passivation layer 40 is deposited on the sidewalls SW of the electrode 30 from the upper space, the degree of the oblique angle of the sidewalls SW will act as one factor affecting the yield rate of the formation. For example, if a sidewall of an electrode is formed to become

“too vertical”, at least one deposition material will be difficult to land on the sidewall. As such, after the deposition, a passivation layer is formed and an air void is formed between the sidewall and the passivation layer as well. If a sidewall of an electrode is formed to become “too horizontal” (i.e., the slope is very gentle), the electrode will occupy a large area.

The oblique angle in the range from about 35 degrees to about 75 degrees can make the deposition material land on the sidewalls SW of the electrode 30 well. The oblique angle at about 45 degrees is the well-trade off between the occupation area and the deposition reliability. In some embodiments, the sidewalls SW of the electrode 30 are absolutely oblique with respect to the passivation layer 24. That is, each of the nitride-based layer 302, the conformal layers 304, 306, 308, and the filling layer 309 has an oblique edge/side surface.

As the passivation layer 40 can cover an entirety of the sidewalls SW of the electrode 30, the passivation layer 40 forms an interface with the sidewall SW of the electrode 30. The interface is oblique with respect to the passivation layer 24. In the present embodiment, the interface is plane.

Referring to FIG. 1A again, the configuration of the electrode 30 can be applied into that of the electrode 32. The passivation layer 40 cover the electrodes 30 and 32. The passivation layer 40 can serve as a planarization layer which has a level top surface to support other layers/elements. In some embodiments, the passivation layer 40 can be formed as being thicker, and a planarization process, such as a chemical mechanical polish (CMP) process, is performed on the passivation layer 40 to remove the excess portions, thereby forming a level top surface. The material of the passivation layer 40 can include, for example but is not limited to, dielectric materials. For example, the passivation layer 40 can include SiNx (e.g., Si₃N₄), SiOₓ, Si₃N₄, SiON, SiC, SiBN, SiCBN, oxides, nitrides, oxides, nitrides, plasma-enhanced oxide (PEOX), or combinations thereof.

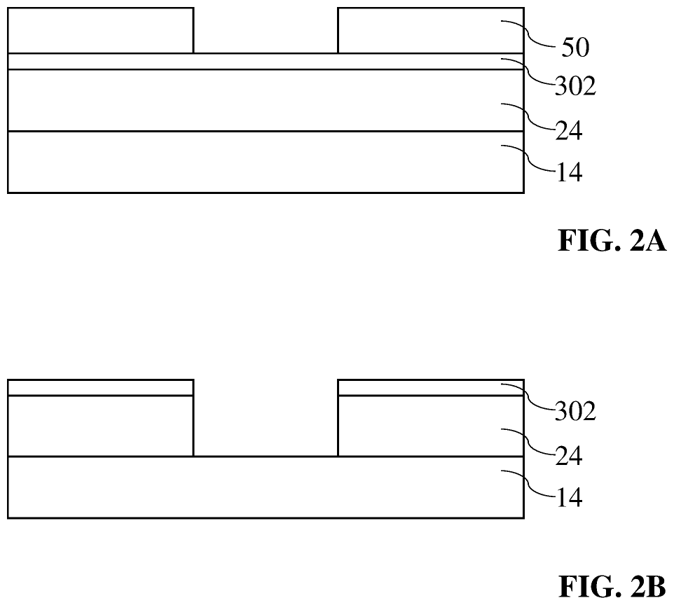

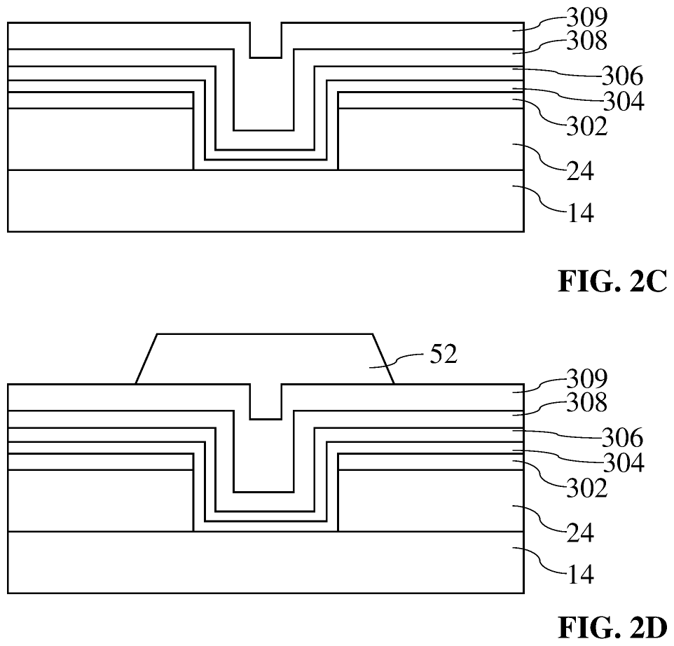

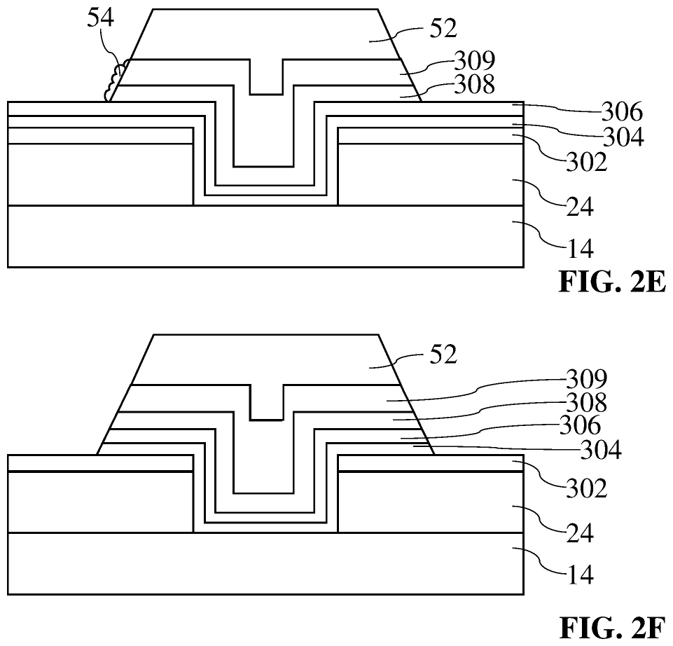

Different stages of a method for manufacturing the semiconductor device 1A are shown in FIG. 2A, FIG. 2B, FIG. 2C, FIG. 2D, FIG. 2E, and FIG. 2F, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a nitride-based semiconductor layer 14 can be formed over/above/on a nitride-based semiconductor layer (e.g., the nitride-based semiconductor layer 12 as shown in FIG. 1A) by using the above-mentioned deposition techniques. A passivation layer 24 can be formed on the nitride-based semiconductor layer 14 by using the above-mentioned deposition techniques. A nitride-based layer 302 can be formed on the passivation layer 24 by using the above-mentioned deposition techniques. A mask layer 50 is formed on the nitride-based layer 302 with an opening so a portion of the nitride-based layer 302 is exposed.

Referring to FIG. 2B, the exposed portion of the nitride-based layer 302 is removed. Then, a portion of the passivation layer 24 beneath the removed portion of the nitride-based layer 302 is removed. The passivation layer 24 can have an opening to expose a portion of the nitride-based semiconductor layer 14.

Referring to FIG. 2C, conformal layers 304, 306, 308, and a filling layer 309 are formed over the nitride-based semiconductor layer 14, the passivation layer 24, and the nitride-based layer 302. The conformal layers 304, 306, 308, and the filling layer 309 can be stacked to act as a conductive layer. The conductive layer is located within the opening of the passivation layer 24 so as to make contact with the nitride-based semiconductor layer 14.

Referring to FIG. 2D, a mask layer 52 is formed to partially cover the filling layer 309 of the conductive layer. Accordingly, at least one portion of the filling layer 309 of the conductive layer is exposed from the mask layer 52.

Referring to FIG. 2E, the exposed portion of the filling layer 309 is removed. Then, a portion of the conformal layer 308 is removed. The removal process can be performed by alternately etching an object and forming a polymer layer on the object. For example, a polymer layer 54 can be formed on the exposed portion of the filling layer 309 of the conductive layer (e.g., be formed on at least one sidewall thereof), and then the polymer layer 54 and bits of the exposed portion of the filling layer 309 are etched. Such the steps can be processed many times (i.e., alternately and continuously), so as to make the sidewall of the remained portion of the filling layer 309 of the conductive layer tilted.

Referring to FIG. 2F, portions of the conformal layers 304 and 306 are removed continuously. During the removal, formation of polymer materials and etching objects are performed alternately and continuously, so the conformal layers 304 and 306 have sidewalls tilted. After the sidewalls of the conformal layers 304 and 306 are tilted, formation of polymer materials and etching objects can be performed alternately and continuously on the nitride-based layer 302, so as to remove excess portions of the nitride-based layer 302 with sidewalls thereof tilted. Accordingly, an ohmic contact electrode can be formed with sidewalls thereof tilted. Thereafter, a passivation layer (e.g., the passivation layer 40) can be formed to cover an entirety of the sidewall of the ohmic contact electrode.

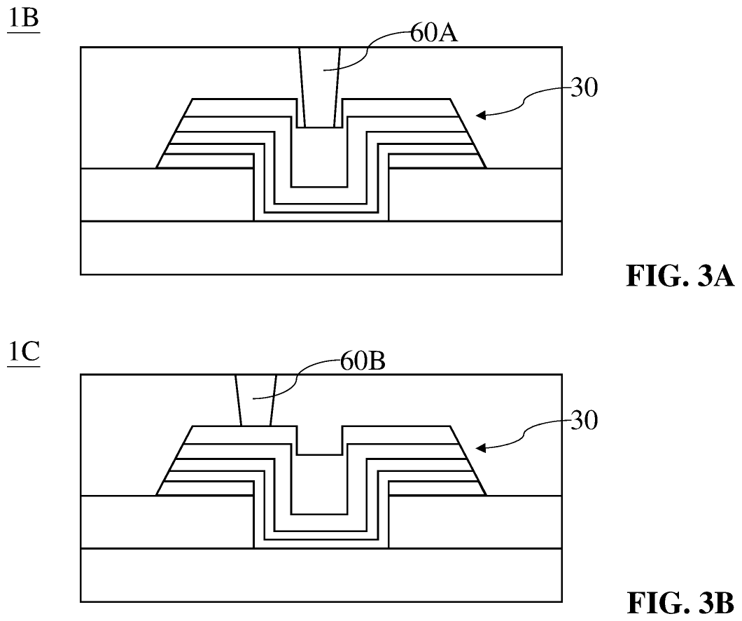

FIG. 3A is a vertical cross-sectional view of a semiconductor device 1B according to some embodiments of the present disclosure. The semiconductor device 1B is similar to the semiconductor device 1A as described and illustrated with reference to FIG. 1A and FIG. 1B, except that the semiconductor device 1B further includes a contact via 60A. The contact via 60A is connected to the top surface of the electrode structure 30. The contact via 60A is located within the recess of the top surface of the electrode structure 30. The exemplary materials of the contact vias 60A can include, for example but are not limited to, conductive materials, such as metals or alloys.

FIG. 3B is a vertical cross-sectional view of a semiconductor device 1C according to some embodiments of the present disclosure. The semiconductor device 1C is similar to the semiconductor device 1B as described and illustrated with reference to FIG. 3A, except that a contact via 60B of the semiconductor device 1C is out of the recess of the top surface of the electrode structure 30. Since the electrode structure 30 is a multiple layered structure. The top surface of the electrode structure 30 may be not unform flat. The contact via 60B is located at a position out of the central line of the electrode structure 30, which tends to land on a flat region of the electrode structure 30.

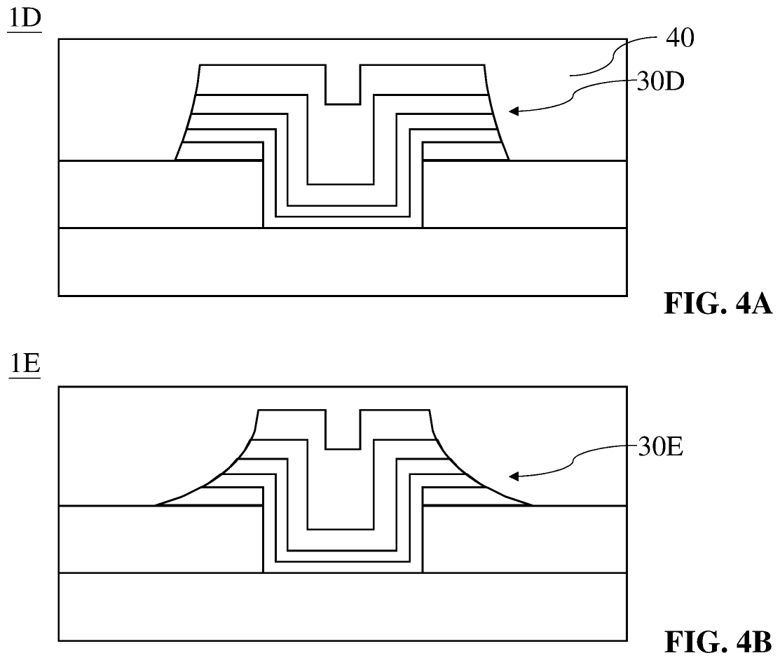

FIG. 4A is a vertical cross-sectional view of a semiconductor device 1D according to some embodiments of the present disclosure. The semiconductor device 1D is similar to the semiconductor device 1A as described and illustrated with reference to FIG. 1A and FIG. 1B, except that an electrode 30D of the semiconductor device 1D has a curved sidewall. The curved sidewall is made for stress consideration. The curved profile can make stress applied on the sidewall more uniform. The curved profile can tend to receive deposition materials during formation of a passivation layer, which can avoid voids created at the sidewall of the electrode 30D.

Accordingly, the passivation 40 can form a curved interface with the sidewall of the electrode 30D.

FIG. 4B is a vertical cross-sectional view of a semiconductor device 1E according to some embodiments of the present disclosure. The semiconductor device 1E is similar to the semiconductor device 1D as described and illustrated with reference to FIG. 4A, except that an electrode 30E of the semiconductor device 1E has a sidewall more curved. The curved profile can tend to receive deposition materials more during formation of a passivation layer since more components of the top surface face an upward direction, which can avoid voids created at the sidewall of the electrode 30E much more. In some embodiments, such the curved profile can made because the electrode 30E is multiple layered structure, which results from different portions of the electrode 30E have different etching rate.

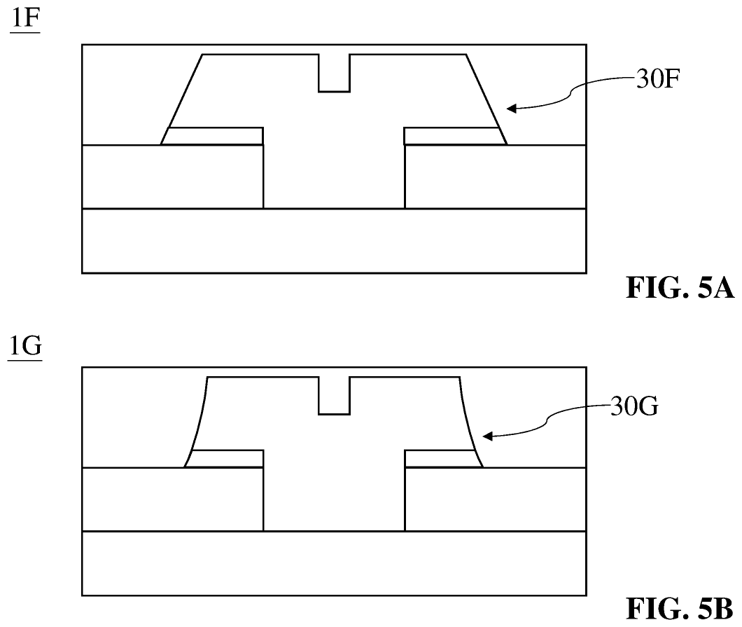

FIG. 5A is a vertical cross-sectional view of a semiconductor device 1F according to some embodiments of the present disclosure. The semiconductor device 1F is similar to the semiconductor device 1A as described and illustrated with reference to FIG. 1A and FIG. 1B, except that an electrode 30F of the semiconductor device 1F is a two-layers structure. The electrode 30F has a plane sidewall.

FIG. 5B is a vertical cross-sectional view of a semiconductor device 1G according to some embodiments of the present disclosure. The semiconductor device 1G is similar to the semiconductor device 1F as described and illustrated with reference to FIG. 5A, except that an electrode 30F of the semiconductor device 1F has a curved sidewall.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first nitride-based semiconductor layer;
a second nitride-based semiconductor layer disposed on the first nitride-based semiconductor layer and having a bandgap greater than a bandgap of the first nitride-based semiconductor layer;
a first passivation layer disposed on the second nitride-based semiconductor layer; and
an electrode structure disposed on the second nitride-based semiconductor layer and the first passivation layer and penetrating the first passivation layer to make contact with the second nitride-based semiconductor layer, wherein the electrode structure has a sidewall extending upward from the first passivation layer and oblique with respect to the first passivation layer.

2. The nitride-based semiconductor device of claim 1, further comprising:
a second passivation layer disposed on the first passivation layer and covering an entirety of the sidewall of the electrode structure.

3. The nitride-based semiconductor device of claim 2, wherein the second passivation layer forms an interface with the sidewall of the electrode structure, and the interface is oblique with respect to the first passivation layer.

4. (canceled)

5. (canceled)

6. The nitride-based semiconductor device of claim 1, wherein the electrode structure comprises:
a nitride-based conductive layer connected to the first passivation layer, wherein the nitride-based conductive layer is free form contact with the second nitride-based semiconductor layer.

7. The nitride-based semiconductor device of claim 1, wherein the sidewall of the electrode structure has an oblique angle with respect to the first passivation layer in a range from 35 degrees to 75 degrees.

8. (canceled)

9. (canceled)

10. The nitride-based semiconductor device of claim 1, wherein the electrode structure has a top surface recessed inward.

11. The nitride-based semiconductor device of claim 10, further comprising:
a contact via connected to the top surface of the electrode structure.

12. The nitride-based semiconductor device of claim 1, wherein the electrode structure is multiple layered.

13. The nitride-based semiconductor device of claim 1, wherein the electrode structure comprises a metal layer, a nitride-based layer, and an aluminum-based layer stacked over the first passivation layer.

14. The nitride-based semiconductor device of claim 13, wherein the sidewall of the electrode structure is formed by the metal layer, the nitride-based layer, and the aluminum-based layer collectively.

15. The nitride-based semiconductor device of claim 1, wherein the sidewall of electrode structure absolutely oblique.

16. A method for manufacturing a nitride-based semiconductor device, comprising:
forming a second nitride-based semiconductor layer on a first nitride-based semiconductor layer;
forming a first passivation layer with an opening over the second nitride-based semiconductor layer;
forming a conductive layer over the first passivation layer and within the opening so as to make contact with the second nitride-based semiconductor layer;
forming a mask layer covering the conductive layer with at least one portion of the conductive layer exposed; and
removing the exposed portion of the conductive layer by alternately etching the exposed portion of the conductive layer and forming a polymer layer on the exposed portion of the conductive layer, so as to make a sidewall of the remained portion of the conductive layer tilted.

17. The method of claim 16, wherein forming the conductive layer comprises stacking the metal layer, the nitride-based layer, and the aluminum-based layer over the first passivation layer.

18. The method of claim 16, further comprising:
forming a second passivation layer to cover an entirety of the sidewall of the conductive layer.

19. The method of claim 16, wherein the sidewall of the conductive layer has an oblique angle with respect to the first passivation layer in a range from 35 degrees to 75 degrees.

20. (canceled)

21. A nitride-based semiconductor device comprising:
a first nitride-based semiconductor layer;
a second nitride-based semiconductor layer disposed on the first nitride-based semiconductor layer and having a bandgap greater than a bandgap of the first nitride-based semiconductor layer;
a first passivation layer disposed on the second nitride-based semiconductor layer; and
an electrode structure disposed on the second nitride-based semiconductor layer and the first passivation layer and penetrating the first passivation layer to make contact with the second nitride-based semiconductor layer; and
a second passivation layer disposed on the second nitride-based semiconductor layer and the first passivation layer and covering a sidewall of the electrode structure, wherein the second passivation layer forms an interface with the sidewall of the electrode structure, and the interface is oblique with respect to the first passivation layer.

22. The nitride-based semiconductor device of claim 21, wherein the sidewall of the electrode structure has an oblique angle with respect to the first passivation layer in a range from 35 degrees to 75 degrees.

23. The nitride-based semiconductor device of claim 21, wherein the sidewall of the electrode structure has an oblique angle with respect to the first passivation layer at about 45 degrees.

24. The nitride-based semiconductor device of claim 21, wherein the interface is plane.

25. The nitride-based semiconductor device of claim 21, wherein the interface is curved.
